(19) United States
(12) Patent Application Publication
(10) Pub. No.: US 2014/0061915 A1
(43) Pub. Date: Mar. 6, 2014

(54) PREVENTION OF THRU-SUBSTRATE VIA PISTONING USING HIGHLY DOPED COPPER ALLOY SEED LAYER

(71) Applicants: Christopher N. Collins, Wappingers Falls, NY (US); Daniel C. Edelstein, White Plains, NY (US); Mukta G. Farooq, Hopewell Junction, NY (US); Troy L. Graves-Abe, Wappingers Falls, NY (US); Andrew H. Simon, Fishkill, NY (US); Richard P. Volant, New Fairfield, CT (US)

(72) Inventors: Christopher N. Collins, Wappingers Falls, NY (US); Daniel C. Edelstein, White Plains, NY (US); Mukta G. Farooq, Hopewell Junction, NY (US); Troy L. Graves-Abe, Wappingers Falls, NY (US); Andrew H. Simon, Fishkill, NY (US); Richard P. Volant, New Fairfield, CT (US)

(73) Assignee: INTERNATIONAL BUSINESS MACHINES CORPORATION, Armonk, NY (US)

(21) Appl. No.: 13/599,295

(22) Filed: Aug. 30, 2012

(51) Int. Cl. H01L 23/532; H01L 21/768

(52) U.S. Cl. 257/751; 438/643; 257/E21.584; 257/E23.161

(57) ABSTRACT

A method of forming an integrated circuit device includes forming a diffusion barrier layer in an opening defined in a substrate; forming a highly doped copper alloy seed layer over the diffusion barrier layer, the copper alloy seed layer having a minority alloy component having a concentration greater than 0.5% atomic; and forming a copper layer over the copper alloy seed layer so as to define a wiring structure of the integrated circuit device.

### BACKGROUND

The present disclosure relates generally to semiconductor device manufacturing techniques and, more particularly, to prevention of thru-substrate via (TSV) pistoning using a highly doped copper alloy seed layer.

The packaging density in electronic industry continuously increases in order to accommodate more electronic devices into a package. In this regard, three-dimensional (3D) wafer-to-wafer stacking technology substantially contributes to the device integration process. Typically, a semiconductor wafer includes several layers of integrated circuitry (e.g., processors, programmable devices, memory devices, etc.) built on a silicon substrate. A top layer of the wafer may be connected to a bottom layer of the wafer through silicon interconnects or vias. In order to form a 3D wafer stack, two or more wafers are placed on top of one other and bonded.

3D wafer stacking technology offers a number of potential benefits, including, for example, improved form factors, lower costs, enhanced performance, and greater integration through system-on-chip (SOC) solutions. In addition, the 3D wafer stacking technology may provide other functionality to the chip. For instance, after being formed, the 3D wafer stack may be diced into stacked dies or chips, with each stacked chip having multiple tiers (i.e., layers) of integrated circuitry. SOC architectures formed by 3D wafer stacking can enable high bandwidth connectivity of products such as, for example, logic circuitry and dynamic random access memory (DRAM), that otherwise have incompatible process flows. At present, there are many applications for 3D wafer stacking technology, including high performance processing devices, video and graphics processors, high density and high bandwidth memory chips, and other SOC solutions.

### SUMMARY

In an exemplary embodiment, a method of forming an integrated circuit device includes forming a diffusion barrier layer in an opening defined in a substrate; forming a highly doped copper alloy seed layer over the diffusion barrier layer, the copper alloy seed layer having a minority alloy component having a concentration greater than 0.5% atomic; and forming a copper layer over the copper alloy seed layer so as to define a wiring structure of the integrated circuit device.

In another embodiment, a method of forming a through-substrate via (TSV) for an integrated circuit device includes forming a diffusion barrier layer in an opening defined in a substrate; forming a copper manganese (CuMn) seed layer over the diffusion barrier layer, the CuMn seed layer having a manganese concentration greater than 0.5% atomic; and forming a copper layer over the copper alloy seed layer.

In another embodiment, an integrated circuit device includes a diffusion barrier layer formed in an opening defined in a substrate; a highly doped copper alloy seed layer formed over the diffusion barrier layer, the copper alloy seed layer having a minority alloy component having a concentration greater than 0.5% atomic; and a copper layer formed over the copper alloy seed layer so as to define a wiring structure of the integrated circuit device.

In still another embodiment, a wiring structure for an integrated circuit device, includes a diffusion barrier layer formed in an opening defined in a substrate; a copper manganese (CuMn) seed layer formed over the diffusion barrier layer, the CuMn seed layer having a manganese concentration greater than 0.5% atomic; and a copper layer formed over the copper alloy seed layer, thereby defining through-substrate via (TSV).

### BRIEF DESCRIPTION OF THE SEVERAL VIEWS OF THE DRAWINGS

Referring to the exemplary drawings wherein like elements are numbered alike in the several Figures:

FIG. 1 is a cross sectional view of various levels of an integrated circuit device which may be formed in accordance with the processing techniques described herein;

FIG. 2 is a focused ion beam (FIB) cut image of a copper filled via that has been delaminated from a barrier layer;

FIG. 3 is an FIB cut image of the via of FIG. 2, following polishing of excess copper and illustrating further delamination up to the polished surface;

FIG. 4 is a scanning electron microscope (SEM) image illustrating separation of through substrate via (TSV) copper from a titanium tungsten (TiW) barrier below;

FIG. 5 is an enlarged view of the SEM image of FIG. 4;

FIG. 6 is a flow diagram illustrating a method of forming a thru-substrate via (TSV) using a highly doped copper alloy seed layer, in accordance with an exemplary embodiment;

FIG. 7 is a cross sectional view of a TSV structure that may be formed in accordance with an exemplary embodiment; and

FIG. 8 is a cross sectional view of a first integrated circuit bonded to and electrically connected to a second integrated circuit using one of more TSV structures as illustrated in FIG. 7.

### DETAILED DESCRIPTION

With respect to 3D wafer stacking technology described above, there are a number of ways chips within a stack may be interconnected. For example, bond pads formed at the surface of each chip may be wire bonded, either to a common substrate or to other chips in the stack. Another example is a so-called “micro-bump” 3D package, where each chip includes a number of micro-bumps that are routed to a circuit board, e.g., along an outer edge of the chip.

Still another way of interconnecting chips within the stack is to use through-substrate vias (TSVs). TSVs extend through a substrate, thereby electrically interconnecting circuits on various chips. Such through-substrate via interconnections can provide advantages in terms of interconnect density as compared to other technologies. In addition to applications in 3D chip stacking, through-substrate via interconnections may also be used to increase performance of radio frequency (RF) and power devices by providing very low resistive ground contacts to a wafer backside, as well as advanced heat sink capability.

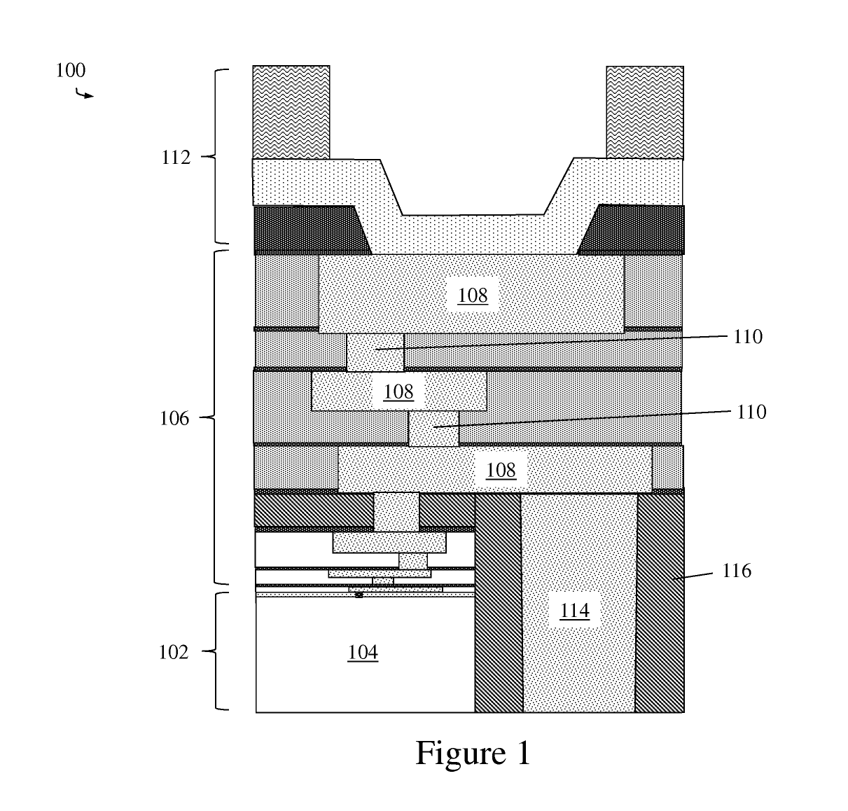

FIG. 1 is a cross sectional view of various levels of an integrated circuit (IC) device 100 which may be bonded to one or more additional devices in accordance with a 3D stacking arrangement. As generally illustrated in FIG. 1, the IC device 100 has a front end of line (FEOL) region 102 where active devices (e.g., transistors) are formed in a semiconductor substrate 104 (e.g., a bulk substrate or a semiconductor-on-insulator substrate). Electrical connections to the active devices in the substrate are made through several wiring levels formed on a back end of line (BEOL) region 106, which generally includes successively larger layers of copper wiring lines 108 connected to other lines by vertical vias 110. At a far BEOL region 112, the IC device is passivated and configured for an eternal connection thereto, such as by a solder connection (not shown).

As indicated above, the IC device 100 may also be bonded and electrically connected to one or more additional substrates (IC devices, not shown) through one or more TSVs 114. Here, a first end of the TSV 114 is shown connected to one of the wiring lines 108 in the BEOL region 106, while the second end of the TSV 114 is configured for bonding to a corresponding TSV in an second substrate (not shown).

The introduction of TSV interconnects, such as TSV 114 in FIG. 1, may present certain challenges. For example, the term “pistoning” refers to a condition in which a via (such as TSV 114) experiences shear stress (e.g., on sidewall surfaces) due a differential of thermal coefficient of expansion (TCE) between the copper via fill material and the surrounding substrate material and/or barrier layers (generally depicted at 116 in FIG. 1). Similar to a mechanical piston, the copper via can actually delaminate and become loose within its surrounding materials. This can, in turn, lead to effects such as device open circuits.

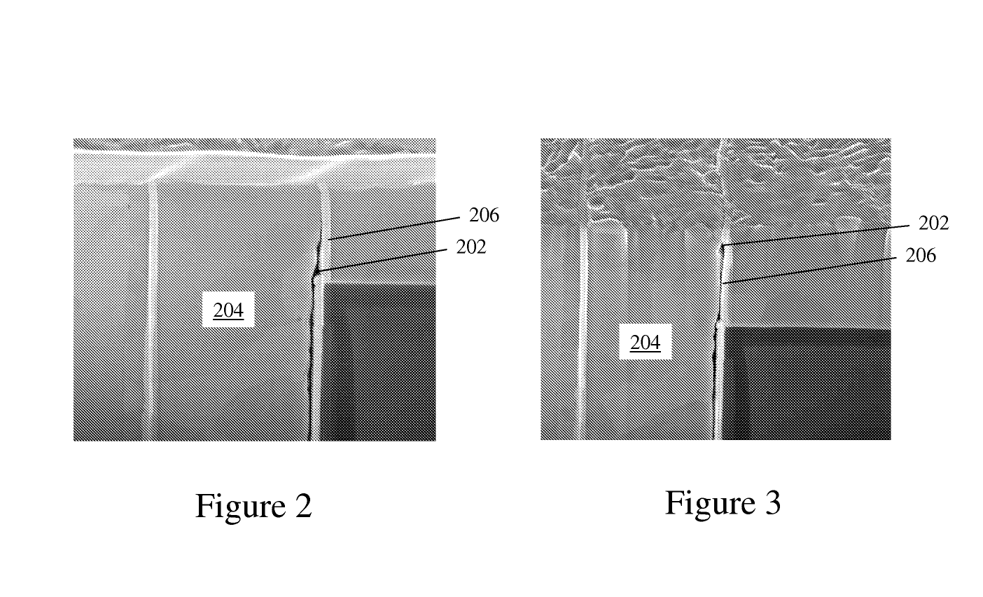

Referring now to FIGS. 2 and 3, there are shown focused ion beam (FIB) cut images of a copper filled via that has become delaminated from a barrier layer. In FIG. 2, a gap 202 is formed between the right side of the via 204 and the barrier layer 206. After polishing, the gap 202 now extends to the polished surface of the via 204 as shown in FIG. 3.

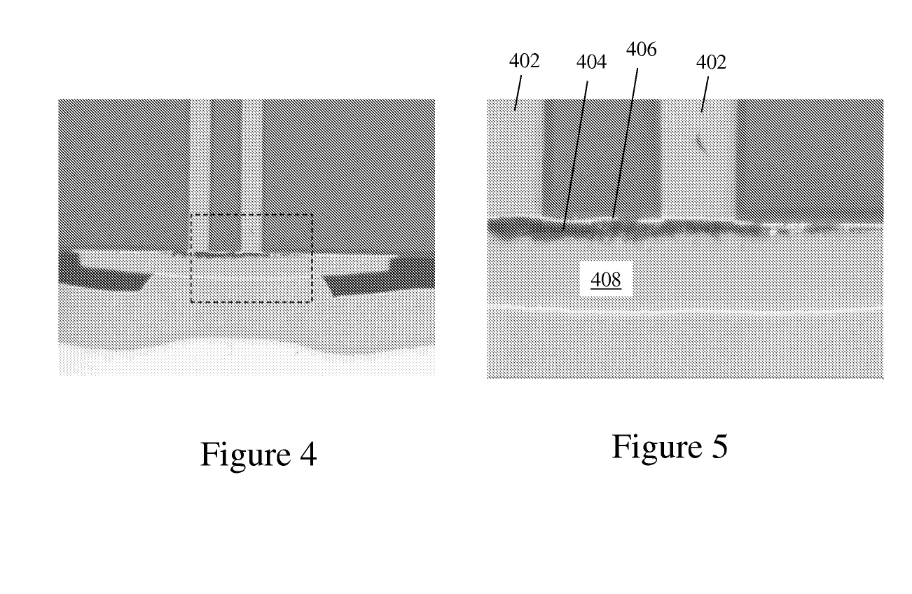

By way of further illustration, FIG. 4 is an SEM image illustrating separation of through substrate via (TSV) copper from a titanium tungsten (TiW) barrier below. FIG. 5 is an enlarged view of the portion of the SEM image of FIG. 4 in the dashed rectangle. As can be particularly seen in FIG. 5, for both TSVs 402, there is a significant gap 404 between the TiW barrier layer 406 and the copper layer 408 beneath the TSVs 402.

In order to address these issues, a copper alloy seed layer having a sufficient dopant metal concentration is introduced in the present embodiments to form wiring structures for IC devices. As used herein, the term “highly doped” copper alloy seed layer refers to a material having a metal dopant concentration greater than 0.5% atomic, and more specifically about 2.0% atomic or greater. A highly doped copper alloy seed layer has been determined to prevent sidewall delamination (i.e., “pistoning”) otherwise caused by high shear stresses at sidewalls and interfaces.

An appropriate alloy component in the seed layer is chosen for its solubility in Cu and its strong bonding to oxygen. Again, the issue with the pistoning behavior of TSVs is that the large difference in coefficient of expansion between substrate and the metallic via results in surface de-adhesion such that the via is mechanically dislodged from the surrounding substrate material (wafer and insulating layers) at the top of the TSV structure. Thus, by introducing the alloy component into the Cu TSV fill material through the alloy seed layer, the mechanical adhesion of the Cu fill material is enhanced such that the shear stresses which result in the de-adhesion of the TSV from the sidewall are mitigated, and mechanical and electrical integrity of the TSV structure are preserved.

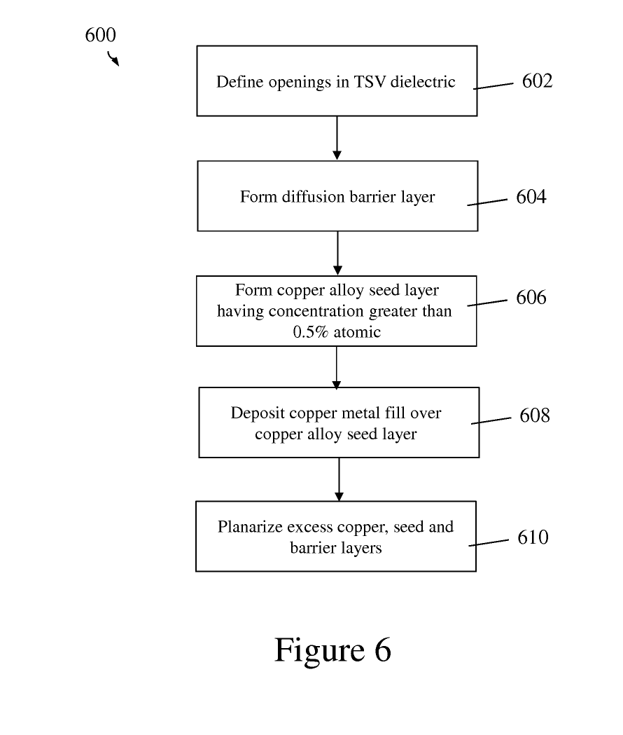

FIG. 6 is a flow diagram illustrating a method 600 of forming a thru-substrate via (TSV) using a highly doped copper alloy seed layer, in accordance with an exemplary embodiment. In block 602, openings are defined in a TSV substrate material, which may be a dielectric such as an oxide layer, nitride layer, or low-k dielectric layer, etc., or semiconductor substrate material such as silicon (Si). Then, in block 604, one or more diffusion barrier layers are formed within the dielectric layer openings. Suitable diffusion barrier layer materials include, for example, one or more of tantalum (Ta), tantalum nitride (TaN), titanium (Ti), titanium nitride (TiN), titanium tungsten (TiW), and the like.

In block 606, a copper alloy seed layer is formed over the diffusion barrier layer. The copper alloy seed layer has a minority alloy component having a concentration greater than 0.5% atomic. Exemplary minority alloy component materials include, but are not limited to, one or more of manganese (Mn), aluminum (Al), zinc (Zn), tin (Sn), and indium (In). In one specific embodiment, the copper alloy seed layer is copper manganese (CuMn) having a manganese concentration of between about 2.0% atomic and about 15% atomic. In a more specific embodiment, the copper alloy seed layer is CuMn having a manganese concentration of about 2.0% atomic. Following the formation of the copper alloy seed layer, copper metal fill is deposited over the seed layer as indicated in block 608. Then, in block 610, the excess copper, seed and barrier layers are planarized before further processing. A copper alloy seed layer of these exemplary concentrations helps to prevent the pumping of the Cu TSV under the influence of subsequent temperature excursions to about 400° C.

In an exemplary embodiment, the dimensions of the TSV may range from about 1 to about 10 microns (μm) in diameter, with a depth of about 10 to about 100 μm, such that the aspect ratio of the TSV is from about 5:1 to about 20:1. In order to successfully fill this structure, a barrier metal layer with an aggregate thickness of about 500 to about 2000 angstroms (Å) is deposited prior to the doped Cu seed layer deposition, with a thickness of about 1000 to about 10,000 Å, depending on feature dimension and geometry. In order to obtain good coverage and morphology of the barrier and seed layers over the entire surface of the TSV, these layers may be deposited with an applied pedestal radiofrequency (RF) bias of about 0.1 to about 2.0 Watts/cm². The seed layer dopant concentration may range from about 0.5% to about 10% (atomic percentage).

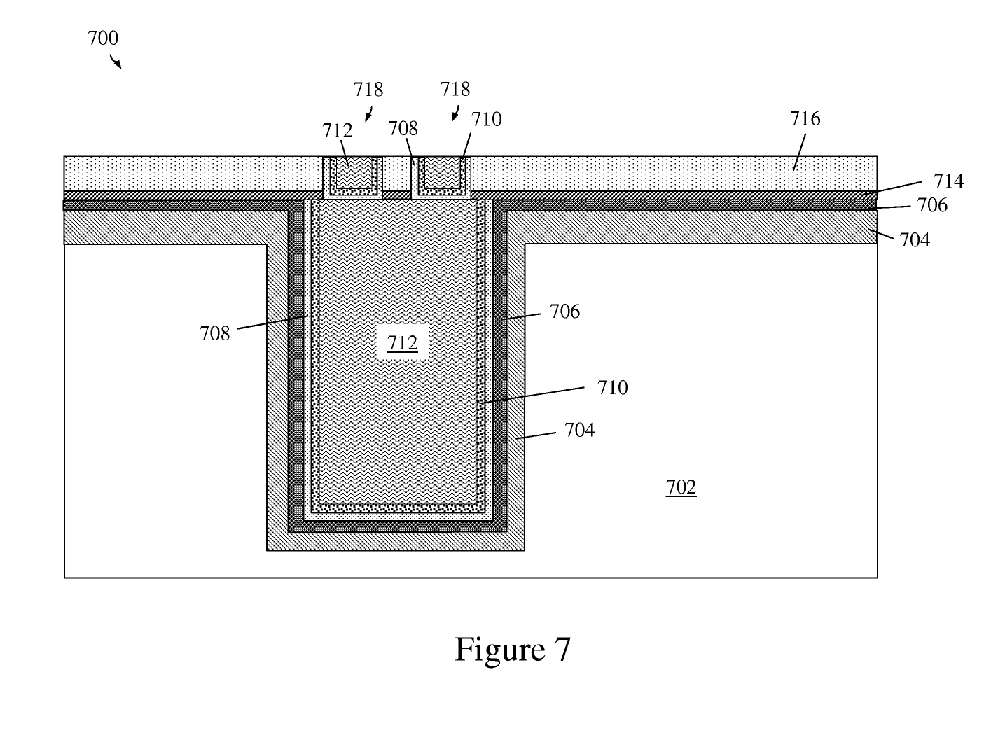

Referring now to FIG. 7, there is shown a cross sectional view of a TSV structure 700 that may be formed in accordance with an exemplary embodiment. The TSV structure 700 is formed within a substrate 702. Again, the substrate 702 may be a semiconductor material such as silicon, and/or include a material such as an oxide layer, nitride layer, or low-k dielectric layer, etc. In the specific embodiment illustrated, once the TSV opening is defined, one or more oxide layers may be formed on the substrate 702, such as a conformal oxide layer 704 and a plasma enhanced (PE) oxide layer 706 formed by plasma enhanced chemical vapor deposition (PECVD).

FIG. 7 further depicts a barrier layer 708 formed on sidewall and bottom surfaces of the PE oxide layer 706. In the embodiment depicted, the barrier layer 708 may be a TaN/Ta barrier layer. The highly doped copper alloy seed layer 710 is formed on the barrier layer 708, followed by the plated copper material 712 that completely fills the opening. Following planarization of the copper material 712, highly doped seed layer 710 and barrier layer 708, a cap layer 714, such as a nitride for example, is formed over the device. This may be followed by a tetraethyl orthosilicate (TEOS) layer 716 formed over the cap layer 714.

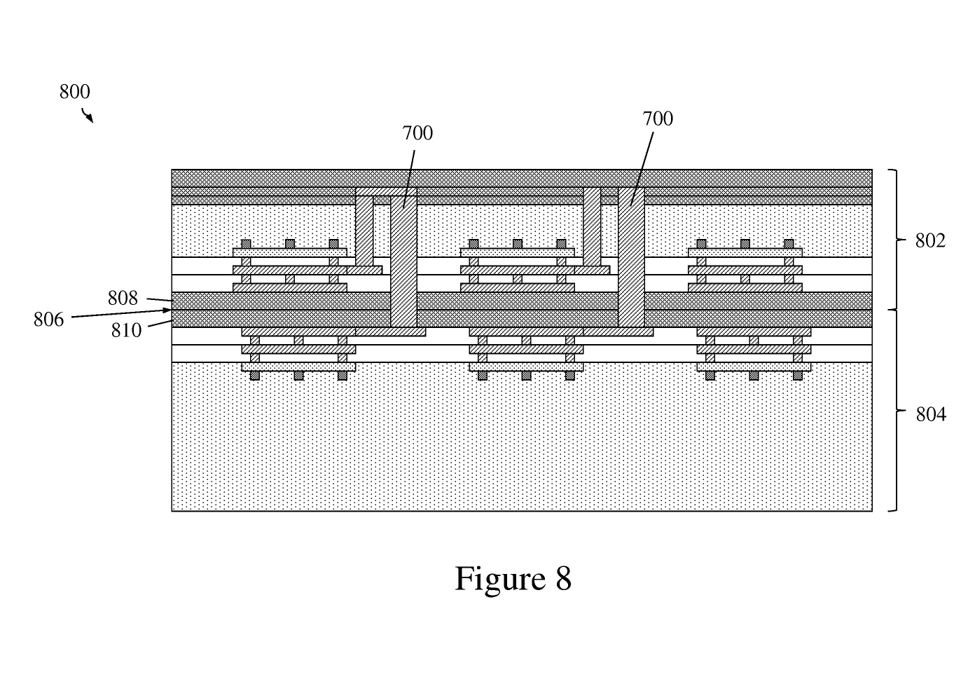

By way of further illustration, a portion of conductive lines 718 are also shown in contact with one end of the TSV structure. As is the case with the TSV structure, the conductive lines 718 may also include with a similarly doped copper alloy seed layer 710 formed on the barrier layer 708. The dopant atoms (e.g., manganese) enhances copper adhesion and prevents pistoning caused by a high Cu—Si TCE differential, that in turn leads to shear-stress on TSV sidewalls and interfaces. Specific examples of the formation of highly doped copper alloy seed layers are discussed in further detail below. A TSV structure such as the TSV structure 700 may be used to electrically connect a first integrated circuit to a second integrated circuit as depicted in FIG. 8.

As particularly shown in FIG. 8, an integrated wafer 800 is formed by bonding a first integrated circuit (IC) 802 to a second IC 804. Where oxide is used as a passivation material for the individual wafers, the bonding may be, for example, oxide-to-oxide bonding (e.g., by surface activation, clean, initial bonding, and annealing), permanent adhesive bonding, or any other suitable technique known in the art that results in a strong bond between electrically insulating layers. Other exemplary techniques may include metal-to-metal thermal compression bonding, or other type of hybrid bonding technique. Thus bonded, the integrated wafer 800 has a bonding interface 806 between layer 808 of the first IC 802 and layer 810 of the second IC 804. As further depicted in FIG. 8, one or more TSV structures 700, such as those described above, pass through layer 808 of the first IC 802 and layer 810 of the second IC 804 so as to electrically interconnect wiring of the first IC 802 to wiring of the second IC 804.

### Example 1

Control cells were built using a standard Cu seed layer in a TSV, and compared to test cells built with a CuMn seed in the TSV. Both cells had identical TSV build methods in all other respects including oxide films, TaN/Ta diffusion barriers, and Cu plating. In each case, the TSV was etched using a Bosch process, then lined with an insulator (comprising a 9 kA sub-atmospheric CVD (SACVD) oxide followed by a 3 kA PECVD cap), a diffusion barrier (TaN/Ta) and a seed layer of either Cu or CuMn. The TSV was then electroplated with Cu using a bottom up fill process, followed by an annealing step, CMP, and an insulating cap deposition.

Both types of cells (i.e., Cu seed layer and CuMn seed layer) were subjected to further processing, i.e., deposition of a TEOS/FTEOS (fluorine doped TEOS) interlevel dielectric and building of the capture level (with a Cu seed). After CMP of the capture level (i.e., the wiring level above the TSV in contact with the TSV), visual observations indicated that the TSV Cu seed control cell showed TSV pistoning whereas the TSV CuMn seed cell did not.

### Example 2

Control cells were built using a standard Cu seed layer in the capture level, and compared to test cells built with a CuMn seed in the capture level. Both cells had identical TSV build methods. In each case, the TSV was etched using a Bosch process, then lined with an insulator (9 kA SACVD oxide followed by a 3 kA PECVD cap), a diffusion barrier (TaN/Ta) and a seed layer of Cu. The TSV was then electroplated with Cu using a bottom up fill process, followed by an annealing step, CMP, and an insulating cap deposition. Both types of cells were subjected to further processing i.e., deposition of a TEOS/FTEOS interlevel dielectric and building of the capture level (with a Cu seed or a CuMn seed). After CMP of the capture level, visual observations indicated that the capture level Cu seed control cell showed TSV pistoning whereas the CuMn seed cell did not.

### Example 3

Combining the structures of the first two examples (i.e. CuMn seed in the TSV as well as in the capture level above the TSV) is also successful in preventing Cu pistoning (based on observations after subsequent BEOL build).

In addition to utilizing a CuMn seed layer in TSV and capture level regions, a highly doped CuMn seed layer may also be used on other wiring levels in contact with the TSV, such as on the grind (back) side of the wafer. Conventionally, the layers formed in this region include a diffusion barrier (e.g., TiW) and Cu seed layer, followed by Cu plating. Thus, embodiments herein also include the use of a diffusion barrier (e.g., TiW, TaN/Ta, TiN/Ti, etc.), and a CuMn seed layer followed by Cu plating. This is expected to address the problem of TiW separation from the seed because of improved adhesion. A specific advantageous embodiment includes TaN/Ta/CuMn for the grind side capture/redistribution level(s).

While the disclosure has been described with reference to a preferred embodiment or embodiments, it will be understood by those skilled in the art that various changes may be made and equivalents may be substituted for elements thereof without departing from the scope of the disclosure. In addition, many modifications may be made to adapt a particular situation or material to the teachings of the disclosure without departing from the essential scope thereof. Therefore, it is intended that the disclosure not be limited to the particular embodiment disclosed as the best mode contemplated for carrying out this disclosure, but that the disclosure will include all embodiments falling within the scope of the appended claims.

1. A method of forming an integrated circuit device, the method comprising:
forming a diffusion barrier layer in an opening defined in a substrate;
forming a highly doped copper alloy seed layer over the diffusion barrier layer, the copper alloy seed layer having a minority alloy component having a concentration greater than 0.5% atomic; and
forming a copper layer over the copper alloy seed layer so as to define a wiring structure of the integrated circuit device, wherein the copper alloy seed layer comprises copper manganese (CuMn) formed over vertical sidewall sections of a through-substrate via (TSV) so as to prevent sidewall delamination of the copper layer of the TSV.

2. The method of claim 1, wherein the minority alloy component of the CuMn seed layer has a concentration of about 2.0% atomic or greater.

3. The method of claim 1, wherein the minority alloy component of the CuMn seed layer has a concentration of about 2.0% atomic.

4-6. (canceled)

7. The method of claim 1, wherein the diffusion barrier layer comprises one or more of tantalum (Ta), tantalum nitride (TaN), titanium (Ti), titanium nitride (TiN), and titanium tungsten (TiW).

8. A method of forming a through-substrate via (TSV) for an integrated circuit device, the method comprising:
forming a diffusion barrier layer in an opening defined in a substrate;
forming a copper manganese (CuMn) seed layer over the diffusion barrier layer, the CuMn seed layer having a manganese concentration greater than 0.5% atomic; and
forming a copper layer over the copper alloy seed layer, wherein the CuMn seed layer is formed over vertical sidewall sections of a through-substrate via (TSV) so as to prevent sidewall delamination of the copper layer of the TSV.

9. The method of claim 8, wherein the CuMn seed layer has a manganese concentration of about 2.0% atomic.

10. The method of claim 9, wherein the diffusion barrier layer comprises one or more of tantalum (Ta), tantalum nitride (TaN), titanium (Ti), titanium nitride (TiN), and titanium tungsten (TiW).

11. The method of claim 8, wherein the TSV has an aspect ratio from about 5:1 to about 20:1.

12. The method of claim 8, wherein the TSV has a diameter of about 1 to about 10 microns (μm), and a depth of about 10 to about 100 μm.

13. An integrated circuit device, comprising:
a diffusion barrier layer formed in an opening defined in a substrate;
a highly doped copper alloy seed layer formed over the diffusion barrier layer, the copper alloy seed layer having a minority alloy component having a concentration greater than 0.5% atomic; and
a copper layer formed over the copper alloy seed layer so as to define a wiring structure of the integrated circuit device, wherein the copper alloy seed layer comprises copper manganese (CuMn), wherein the wiring structure comprises a through-substrate via (TSV), and wherein the CuMn seed layer is formed over vertical sidewall sections of the TSV so as to prevent sidewall delamination of the copper layer of the TSV.

14. The device of claim 13, wherein the minority alloy component of the CuMn copper alloy seed layer has a concentration of about 2.0% atomic or greater.

15. The device of claim 13, wherein the minority alloy component of the CuMn copper alloy seed layer has a concentration of about 2.0% atomic.

16-18. (canceled)

19. The method of claim 13, wherein the diffusion barrier layer comprises one or more of tantalum (Ta), tantalum nitride (TaN), titanium (Ti), titanium nitride (TiN), and titanium tungsten (TiW).

20-22. (canceled)

23. The structure of claim 13, wherein the TSV has an aspect ratio from about 5:1 to about 20:1.

24. The structure of claim 13, wherein the TSV has a diameter of about 1 to about 10 microns (μm), and a depth of about 10 to about 100 μm.

25. The structure of claim 13, wherein the TSV electrically interconnects a first integrated circuit and a second integrated circuit.
